(19) United States
(12) Patent Application Publication
(10) Pub. No.: US 2019/0072830 A1
(43) Pub. Date: Mar. 7, 2019

(54) Method of Manufacturing Pixel Structure

(71) Applicants: HKC Corporation Limited, Shenzhen (CN); Chongqing HKC Optoelectronics Technology Co., Ltd., Chongqing (CN)

(72) Inventor: Yu-Jen Chen, Chongqing (CN)

(21) Appl. No.: 15/567,264

(22) PCT Filed: Apr. 27, 2017
(86) PCT No.: PCT/CN2017/082109

§ 371 Date: Oct. 17, 2017

(30) Foreign Application Priority Data
Dec. 30, 2016 (CN) 201611270944.4

(51) Int. Cl. G02F 1/1362; G02F 1/1343; H01L 27/12

(52) U.S. Cl. CPC G02F 1/136213; G02F 1/13624; G02F 2201/123; G02F 1/1343; H01L 27/124; G02F 1/136286

(57) ABSTRACT

A method of manufacturing a pixel structure is provided. The method includes: forming a first conductive layer on a substrate, forming a second conductive layer on the substrate, and forming a third conductive layer on the substrate. Wherein, the first conductive layer, the second conductive layer and the third conductive layer are disposed to be overlapped and at a distance separated from each other. The first conductive layer, the second conductive layer and the third conductive layer are overlapped with each other in a vertical space. Further, an active switch is formed in a pixel area after forming the first conductive layer, wherein the first conductive layer is coupled to a drain electrode of the active switch. The second conductive layer is coupled to a first voltage line. The third conductive layer is coupled to a second voltage line.

### CROSS-REFERENCE TO RELATED APPLICATION

This application claims the benefit of China Patent Application No. 201611270944.4, filed on Dec. 30, 2016, in the State Intellectual Property Office of the People's Republic of China, the disclosure of which is incorporated herein in its entirety by reference.

### BACKGROUND OF THE INVENTION

### 1. Field of the Invention

The present disclosure is related to a method of manufacturing a pixel structure, in particular, is related to a method of manufacturing a pixel structure which is able to relieve crosstalk effect.

### 2. Description of the Related Art

In recent years, depending on the advances of technologies, various display devices such as Liquid crystal displays (LCDs) or Electro Luminescence (EL) display apparatus are widely applied in flat displays. In terms of LCDs, most of the LCDs are backlight type liquid crystal displays, which are formed by display panels and backlight modules. The display panel is formed by two transparent substrates and liquid crystals encapsulated in the substrates.

Presented LCDs usually provide data signals by a plurality of pixel electrodes respectively based on image information, then control the transmittance of a plurality of pixel units to display demanded images. In particular, each of pixel electrodes is coupled to data lines and scan lines individually, of which the scan lines are coupled to the pixel electrodes by TFTs. By controlling and turning on the TFTs, the data lines charge the pixel electrodes. However, during the charging process, a plurality of parasitic capacitors may be generated. The plurality of parasitic capacitors may cause the voltage of the pixel electrodes being shared because of crosstalk effect, thereby resulted in insufficient voltage of the pixel electrodes and leads to abnormally colors displayed. Furthermore, along with higher resolution, the crosstalk effect becomes more obvious.

### SUMMARY OF THE INVENTION

The technical problem to be solved in the present disclosure is to provide a method of manufacturing a pixel structure which is able to relieve crosstalk effect. A purpose of the present disclosure is to provide a method of manufacturing a pixel structure. The method comprises: forming a first conductive layer on a substrate, forming a second conductive layer on the substrate, and forming a third conductive layer on the substrate. Wherein, the first conductive layer, the second conductive layer and the third conductive layer are disposed to be overlapped and at a distance separated from each other. The first conductive layer, the second conductive layer and the third conductive layer are overlapped with each other in a vertical space. Further, an active switch is formed in a pixel area after forming the first conductive layer, wherein the first conductive layer is coupled to a drain electrode of the active switch. The second conductive layer is coupled to a first voltage line. The third conductive layer is coupled to a second voltage line.

In some embodiments, a scan line is formed on the substrate when forming the first conductive layer.

In some embodiments, a pixel electrode is formed on the substrate when forming the second conductive layer.

In some embodiments, when forming the third conductive layer, the material of the third conductive layer is the same as the material of a first metal layer or a second metal layer of the active switch.

In some embodiments, at least one of the first conductive layer, the second conductive layer and the third conductive layer is formed of the material same as the first metal layer of the active switch.

In some embodiments, at least one of the first conductive layer, the second conductive layer and the third conductive layer is formed of the material same as the second metal layer of the active switch.

In some embodiments, at least one of the first conductive layer, the second conductive layer and the third conductive layer is formed of a transparent conductive material.

Another purpose of the present disclosure is to provide a method of manufacturing a pixel structure. The method comprises: forming a first conductive layer on a substrate, forming a second conductive layer on the substrate, and forming a third conductive layer on the substrate. Wherein, the first conductive layer, the second conductive layer and the third conductive layer are disposed to be overlapped and at a distance separated from each other. The first conductive layer, the second conductive layer and the third conductive layer are overlapped with each other in a vertical space. Further, an active switch is formed in a pixel area after forming the first conductive layer, wherein the first conductive layer is coupled to a drain electrode of the active switch. The second conductive layer is coupled to a first voltage line. The third conductive layer is coupled to a second voltage line.

Wherein, a scan line is formed on the substrate when forming the first conductive layer.

Wherein, a pixel electrode is formed on the substrate when forming the second conductive layer.

Wherein, when forming the third conductive layer, the material of the third conductive layer is the same as the material of a first metal layer or a second metal layer of the active switch.

In the present disclosure, manufacturing process may be integrated in order to form two storage capacitors in the pixel structure. Simultaneously, the value of the pixel voltage of the pixel structure may be kept so as to reduce the influence of parasitic capacitors, thereby resulted in relieving of influence of crosstalk effect. Thus, the display panel may display normally.

### BRIEF DESCRIPTION OF THE DRAWINGS

Appended drawings are to be used for making the embodiments of the present disclosure to be further understood. The drawings form a part of the specification, and are to be used for demonstrating the embodiments of the present disclosure and for explaining the principle of the present disclosure by a combination with the description text. Obviously, the following appended drawings are merely some embodiments of the present disclosure. A person having ordinary skill in the art is able to obtain other drawings according to these appending drawings without under the premise of paying creative labor. In the appended drawings:

FIG. 1 is a structural schematic view of a pixel structure of the present disclosure.

FIG. 2 is a structural schematic view of a pixel structure of the present disclosure.

FIG. 3 is a structural schematic view of a pixel structure of the present disclosure.

FIG. 4 is a structural schematic view of a pixel structure of the present disclosure.

FIG. 5 is a schematic view of a circuit of a pixel structure of the present disclosure.

FIG. 6 is a schematic view of a circuit of a pixel structure of the present disclosure.

FIG. 7 is a schematic view of a circuit of a pixel structure of the present disclosure.

FIG. 8 is a schematic view of a circuit of a pixel structure of the present disclosure.

FIG. 9 is a structural schematic view of a pixel structure of an embodiment of the present disclosure.

FIG. 10 is a structural schematic view of a pixel structure of an embodiment of the present disclosure.

FIG. 11 is a structural schematic view of a pixel structure of an embodiment of the present disclosure.

FIG. 12 is a structural schematic view of a pixel structure of an embodiment of the present disclosure.

FIG. 13 is a schematic view of a pixel circuit structure of an embodiment of the present disclosure.

FIG. 14 is a schematic view of a pixel circuit structure of an embodiment of the present disclosure.

FIG. 15 is a schematic view of the arrangement of a first conductive layer, a second conductive layer and a third conductive layer of an embodiment of the present disclosure.

FIG. 16 is a schematic view of the arrangement of a first conductive layer, a second conductive layer and a third conductive layer of an embodiment of the present disclosure.

FIG. 17 is a schematic view of the arrangement of a first conductive layer, a second conductive layer, a third conductive layer and a fourth conductive layer of an embodiment of the present disclosure.

### DESCRIPTION OF THE PREFERRED EMBODIMENTS

Features, particular structures and functional details disclosed herein are merely representative, and are for a purpose of describing the exemplary embodiments of the present disclosure. It is to be understood that the present invention may be implemented in different forms, and should not be limited to the embodiments described herein.

In the description of the present disclosure, it is to be under stood that terms of “center”, “lateral”, “up”, “down”, “left”, “right”, “vertical”, “horizontal”, “top”, “bottom”, for describing position relationship are based on the relationship shown in the appended drawings. These are used for ease of describing the present disclosure and simplifying the description, but not for indicating or implying that specific devices or elements must be in a specific position, be formed and be operated in a specific direction. Hence, they should not be realized as a limitation of the present disclosure. In addition, the terms of “the first” and “the second” are only used for describing, and should not be realized as indicating or an implying their relative importance or implying a number of specific technical features. Thus, the features limited by “the first” and “the second” may indicate or imply that it comprises one or more of the same features. In the description of the present disclosure, “a plurality of” means two or more than two unless otherwise indicated. Furthermore, the term “comprises” or any derivatives thereof means intended to cover the inclusion without exclusion.

In the description of the present disclosure, it is to be explained that terms of “install”, “link”, “connect” should be understood broadly unless otherwise regulated or limited. For instance, they may be as a fixed connection, detachably connection, integrally connection, mechanically connection, directly connection, a connection with an intermediate media or a connection within two elements. A person skilled in the related art is able to understand the substantially meaning of the terms in the disclosure according to a substantially case.

The terminologies used herein are only used for describing particular embodiments but not limiting exemplary embodiments. All of terms used herein as a single form such as “a”, “one of” also imply a plurality form unless otherwise mentioned. It is to be further understood is that the terms of “comprises” and/or “include” regulating the present of the described features, integers, steps, operations, units and/or components do not exclude the present or adding one or more features, integers, steps, operations, units and/or components.

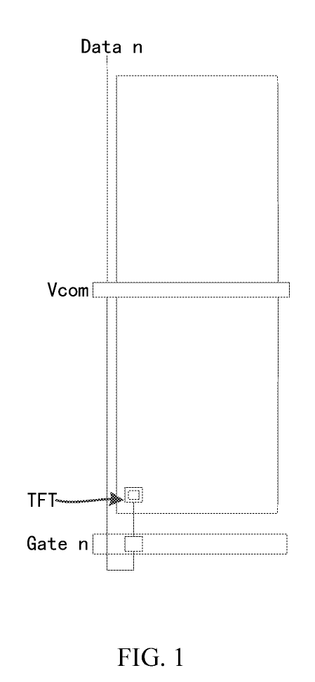

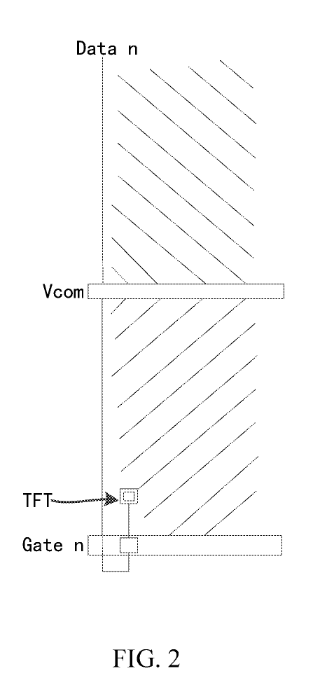

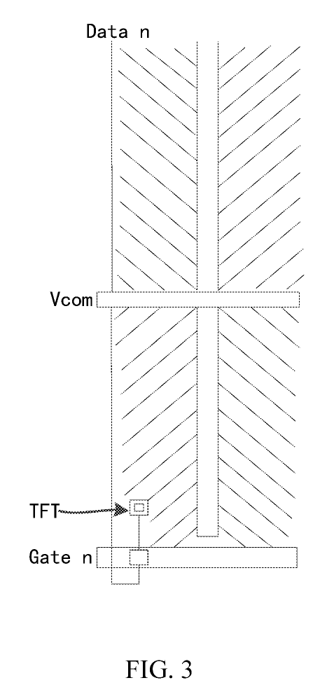

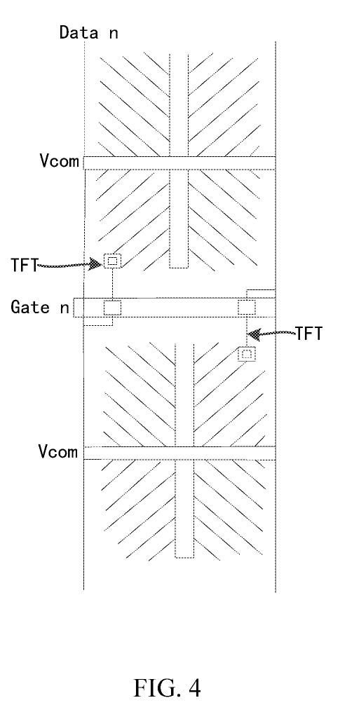

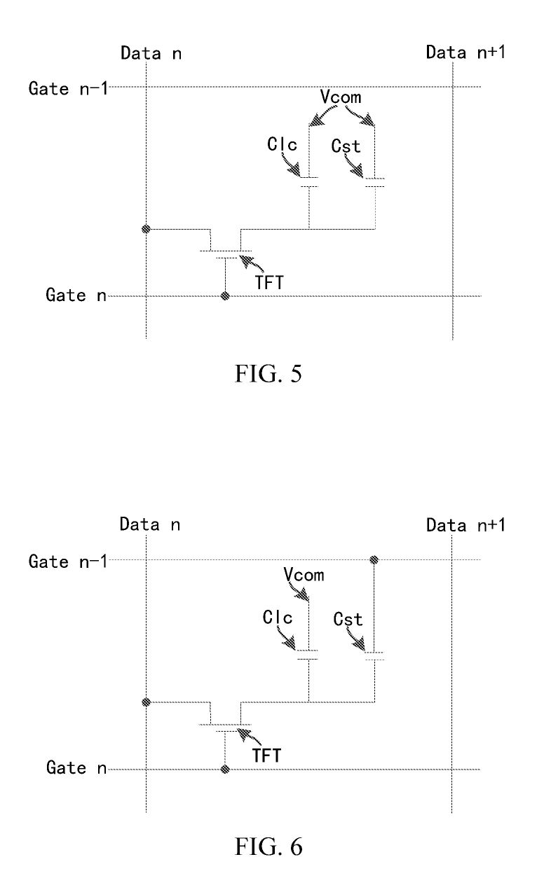

Since charging time during a single charging is relatively short, the applicant designs a pixel structure for keeping the voltage Vpixel of the pixel structure, as shown in FIGS. 1-8. In particular, the pixel structures are coupled to a present data line Data n and a present scan line Gate n individually. The present scan line is coupled to the pixel structure by an active switch TFT. The active switch TFT is turned on by the present scan line. The present data line Data n charges the pixel structure. The present data line Data n charges a pixel capacitor Clc and a storage capacitor Cst by its charging voltage (Vdata) during charging the pixel structure. The pixel structure keeps the value of a voltage (Vpixel) of the pixel structure by the storage capacitor Cst so that the display panel may display normally.

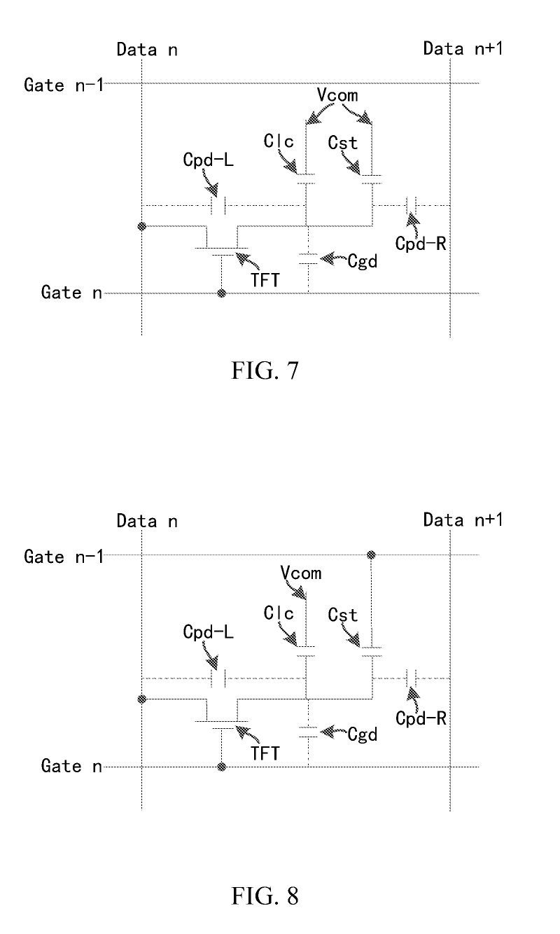

However, during the display process of the display panel, various gray scales may be displayed. The voltage of present dada line Data n charging the pixel structure may be varied continuously, so that the voltage of the pixel structure may be varied correspondingly. Since several parasitic capacitors (Cpd-L, Cgd and Cpd-R) are presented because of the charging voltage of the present data line and the pixel structure presents, as dotted lines shown in FIGS. 7-8, the capacitors between the dotted lines are the several parasitic capacitors of which the several parasitic capacitors (Cpd-L, Cgd and Cpd-R) may lead to the sharing of the voltage of the pixel structure because of crosstalk effect, and may result in insufficient voltage of the pixel structure and further lead to abnormally colors displayed.

For reducing the influence of the several parasitic capacitors and relieving the influence of the crosstalk effect, the applicant further utilizes two methods as follows.

One of which is to dispose the data line far away from the pixel structure so as to reduce the generating of parasitic capacitors and to further reduce the influence of the crosstalk effect. However, this increases the plane area of the display panel, so it is not easy to be used in a display panel having higher resolution.

Another of which is to increase the storage capacitor Cst and to make it far larger than the parasitic capacitors (Cpd-L, Cgd and Cpd-R) so as to reduce the influence of the crosstalk effect. However, the conductive layer within the storage capacitor should be increased so that the plane area of the pixel structure may be increased. Along with higher resolution, the spaces for pixel electrodes may be smaller and the disposition of the storage capacitors may be smaller. Hence, increasing the volume of the storage capacitors is also not easy to be used in a display panel having higher resolution. Since the limitation of the plane area of the storage capacitors, the reduced efficiency of the crosstalk effect achieved by increasing the storage capacitors is also reduced.

Hence, the applicant designs another technical solution to solve the above problems. In particular, as follows:

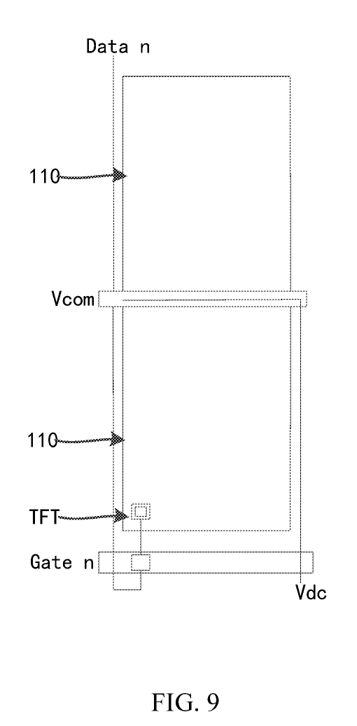

Here, FIGS. 9-16 are used for detailed description of the present disclosure in a combination with preferred embodiments.

As shown in FIGS. 9-16, an embodiment of the present disclosure discloses a pixel structure and a pixel circuit. The pixel structure and the pixel circuit structure of the present embodiment may be as several types. The several kinds of the pixel structure may be applied in various types of display devices individually. For instance, the pixel structure of the present disclosure may be applied in several types display devices as follows: Twisted Nematic (TN) type, Super Twisted Nematic (STN) type, In-Plane Switching (IPS) type, Vertical Alignment (VA) type, High Vertical Alignment (HVA) type, and curve surface type display panels.

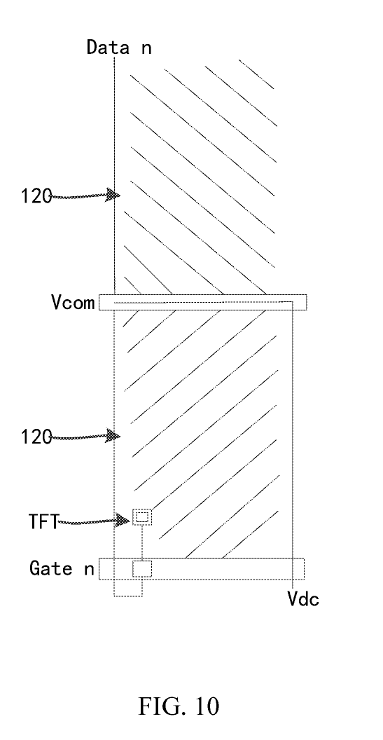

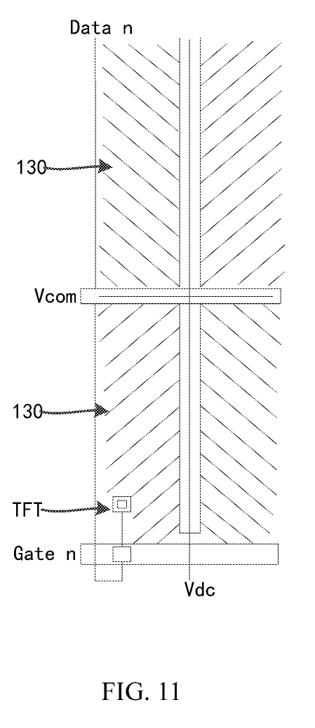

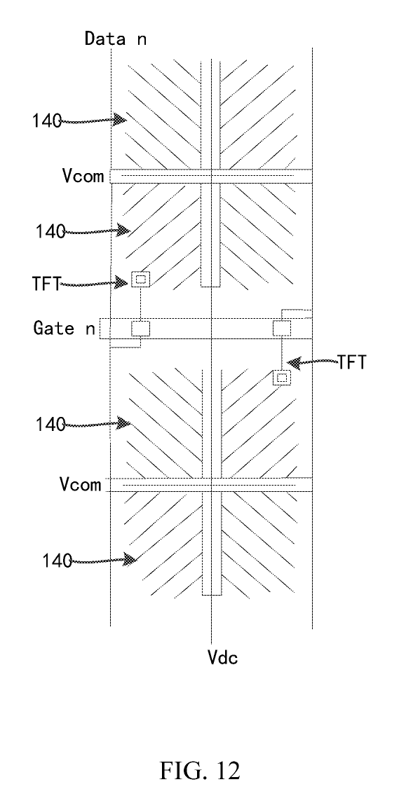

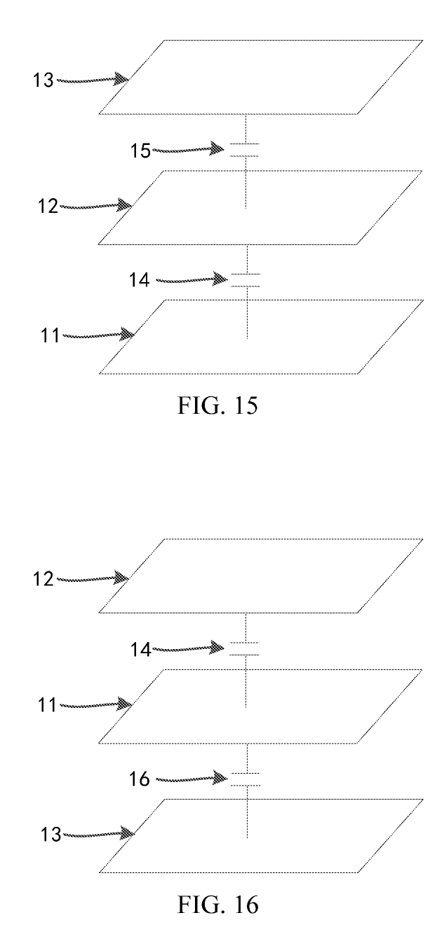

In particular, the pixel structures of embodiments of the present disclosure may be 4 different types of pixel structures as shown in FIGS. 9-12. It has to be explained that FIGS. 9-12 are only several example types of the pixel structures of the embodiments of the present disclosure for description. The pixel structures of embodiments of the present disclosure are not limited to these 4 types of structures. The pixel structures of the embodiments of the present disclosure comprises a pixel electrode, wherein FIG. 9 shows a pixel structure of the present disclosure of which the pixel structure comprises a first pixel electrode 110; FIG. 10 shows another pixel structure of the present disclosure of which the pixel structure comprises a second pixel electrode 120; FIG. 11 shows yet another pixel structure of the present disclosure of which the pixel structure comprises a third pixel electrode 130; FIG. 12 shows yet another pixel structure of the present disclosure of which the pixel structure of which the pixel structure comprises a fourth pixel electrode 140.

Wherein, the pixel structure of the embodiments of the present disclosure comprises a first conductive layer 11, a second conductive layer 12 and a third conductive layer 13. As shown in FIGS. 15 and 16, the first conductive layer 11 is coupled to a drain electrode of an active switch (e.g. TFT, but is not limited to TFT) TFT. The second conductive layer 12 is coupled to a first voltage line. The third conductive layer 13 is coupled to a second voltage line. The first conductive layer 11, the second conductive layer 12 and the third conductive layer 13 are all disposed to be overlapped and at a distance separated from each other. The first conductive layer, the second conductive layer and the third conductive layer are overlapped with each other in a vertical space.

In comparison with the recent techniques, the three conductive layer of the pixel structure of the embodiments of the present disclosure may all be electrified and three of which may form two storage capacitors. The two storage capacitors may keep the pixel voltage value of the pixel structure simultaneously so as to reduce the influences of the several parasitic capacitors, and further to relieve the influence of crosstalk effect. Thus the display panel may display normally.

Furthermore, the embodiments of the present disclosure keep the value of the pixel structure by the two storage capacitors may have better effect for keeping the voltage value of the pixel structure and may make the voltage value more stable in comparison with the pixel strictures shown in FIGS. 1-8, which keep the voltage value of the pixel structure by one storage capacitor. Simultaneously, the embodiments of the present disclosure directly dispose the first conductive layer, the second conductive layer and the third conductive layer to be overlapped so that they are no need of increasing the plane area of each conductive layer. Hence, the embodiments of the present disclosure may greatly increase the capacitance of the pixel structure without improve the plane area of each conductive layer. Thus, the voltage value of the pixel structure may be kept better so that the disclosure may be more adapted to a display panel having high resolution.

In some embodiments, more stacked conductive layers may be formed in the pixel structure so that more storage capacitors (the fourth storage capacitors, the fifth storage capacitors) may be formed in the pixel structure.

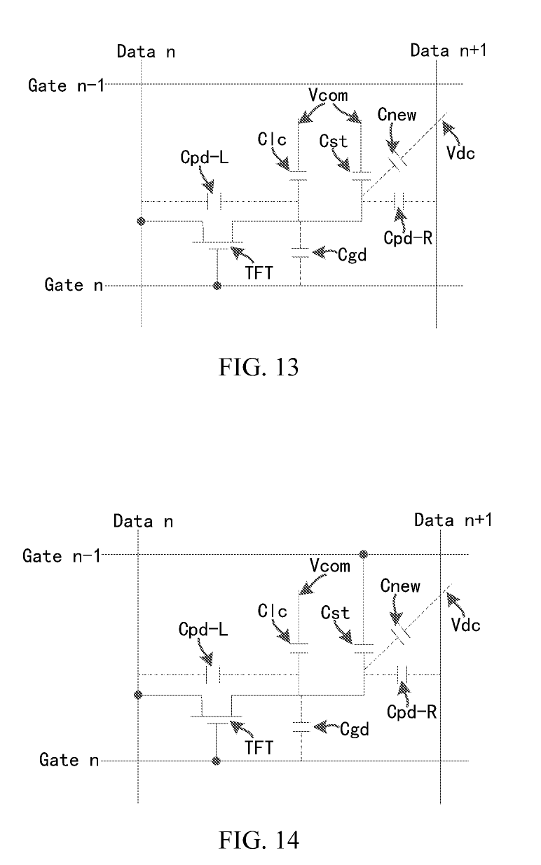

In an embodiment of the present disclosure as shown in FIG. 16, FIG. 16 is a particular way of overlapping the first conductive layer, the second conductive layer and the third conductive layer. In particular, a first conductive layer 11 is disposed between a second conductive layer 12 and a third conductive layer 13, so that a first storage capacitor 14 is formed between the first conductive layer 11 and the second conductive layer 12. As shown in a combination of FIGS. 13 and 14, the first storage capacitor 14 is the storage capacitor Cst. When the pixel structure utilizes a structure as shown in FIG. 16, in this case, the storage capacitor Cst is defined as a storage capacitor 14. A second storage capacitor 16 is formed between the first conductive layer 11 and the third conductive layer 13. The second storage capacitor 16 is a storage capacitor Cnew, in this case, the storage capacitor Cnew is defined as the second storage capacitor 16. Hence, the two storage capacitors (the first storage capacitor 11, the second storage capacitor 16) both keep the electric potential of the voltage of the pixel structure without affecting the voltage of the pixel structure because of the change of the charging voltage of the present data line during the charging process, thus relieve crosstalk effect.

However, it has to be explained that FIG. 16 is merely a particular conductive layer structure arrangement, and it may be other kinds of structure arrangement. For instance, as shown in FIG. 15, FIG. 16 is another particular way of overlapping the first conductive layer, the second conductive layer and the third conductive layer. In particular, a second conductive layer 12 is disposed between a first conductive layer 11 and a third conductive layer 13, so that the same storage capacitor as shown in FIG. 16 may be formed between the first conductive layer 11 and the second conductive layer 12, that is, the first storage capacitor 14. Similarly, as shown in a combination of FIGS. 13 and 14, the first storage capacitor is the storage capacitor Cst, in this case, the storage capacitor Cst is defined as the first storage capacitor 14. A third storage capacitor 15 is formed between the second conductive layer 12 and the third conductive layer 13. Similarly, as shown in a combination of FIGS. 13 and 14, the third storage capacitor 15 may be indicated as the storage capacitor Cnew (however, it has to be explained that since only one new storage capacitor may be indicated in FIGS. 13 and 14, that is, the second storage capacitor or the third storage capacitor, hence, the Cnew in FIGS. 13 and 14 are merely used for explaining the second storage capacitor or the third storage capacitor. In this case, the second storage capacitor and the third storage capacitor are not the same), in this case, when the pixel structure utilizes the structure shown in FIG. 15, the storage capacitor Cnew is defined as the third storage capacitor 15. Hence the two storage capacitors (the first storage capacitor 11, the second storage capacitor 16) both keep the electric potential of the voltage of the pixel structure without affecting the voltage of the pixel structure because of the change of the charging voltage of the present data line during the charging process, thus relieve crosstalk effect.

In the following descriptions, the second storage capacitor and the third capacitor will be replaced by Cnew in the present embodiment.

As shown in FIGS. 13 and 14, the first conductive layer 11 is coupled to the drain electrode of an active switch. An end of a pixel capacitor Clc is coupled to a common line Vcom. The pixel capacitor Clc is coupled to the active switch. The active switches are coupled to a present data line Data n and a present scan line Gate n, individually. When the present scan line controlling to open the active switches, the present data line charges the pixel structure through the active switches.

Further, the first voltage line comprises a previous scan line Gate n−1. As shown in FIG. 14, that is, the second conductive layer 12 is coupled to the previous scan line. The charging process of the pixel structure is controlling the active switch to be turned on by the present scan line Gate n, so that the present data line Data n charges the pixel structure. The previous scan line is in a previous row of the present scan line. By previously charging the second conductive layer 12 by the previous scan line and make the second conductive layer 12 having a voltage, the charging time may be reduced when the present data line is charging. Further, the second conductive layer may achieve a predetermined electric potential quickly. This is a particular way that the conductive layer couples with the first voltage line. Surely, it has to be explained that the second conductive layer may also be coupled to other first voltage lines. For instance, as shown in FIG. 13, the first voltage line comprises a common line Vcom, that is, the second conductive layer 12 is coupled to the common line Vcom, and the common line Vcom charges the second conductive layer. The structure of this way is easy.

In an embodiment of the present disclosure, the third conductive layer 13 is coupled to the second voltage line. As shown in FIGS. 9-14, the second voltage line Vdc of an embodiment of the present disclosure is coupled to a DC voltage. The voltage range of the common line which the second conductive layer is connected is, for example, 7.5V to 0V; the voltage range of the data line is −5 to 15V; the voltage range of the scan line is −6 to 35V. Since the voltage of the third conductive layer connected with the second voltage line is different from all of the voltages of the first conductive layer and the second conductive layer, a storage capacitor may be formed between the third conductive layer and the first conductive layer or the second conductive layer.

In the embodiments of the present disclosure, as shown in FIGS. 9-12 and 17, the method of manufacturing a pixel structure may comprise: forming a first conductive layer 11 on a substrate 101 (e.g. the transparent substrate of the active switch array substrate), forming a second conductive layer 12 on the substrate 101, and forming a third conductive layer 13 on the substrate 101. Wherein, the first conductive layer 11, the second conductive layer 12 and the third conductive layer 13 are disposed to be overlapped and at a distance separated from each other. The first conductive layer 11, the second conductive layer 12 and the third conductive layer 13 are overlapped with each other in a vertical space. Further, an active switch TFT is formed in a pixel area after forming the first conductive layer 11, wherein the first conductive layer 11 is coupled to a drain electrode of the active switch TFT. The second conductive layer 12 is coupled to a first voltage line. The third conductive layer 13 is coupled to a second voltage line.

Wherein, insulating layers 102 is presented between the first conductive layer 11, the second conductive layer 12 and the third conductive layer 13 so that the first conductive layer 11, the second conductive layer 12 and the third conductive layer 13 may be insulated.

In some embodiments, a fourth conductive layer 131 may be formed on the third conductive layer 13 after forming the third conductive layer 13, of which the first conductive layer 11, the second conductive layer 12, the third conductive layer 13 and the fourth conductive layer 131 are disposed to be overlapped and at a distance separated from each other.

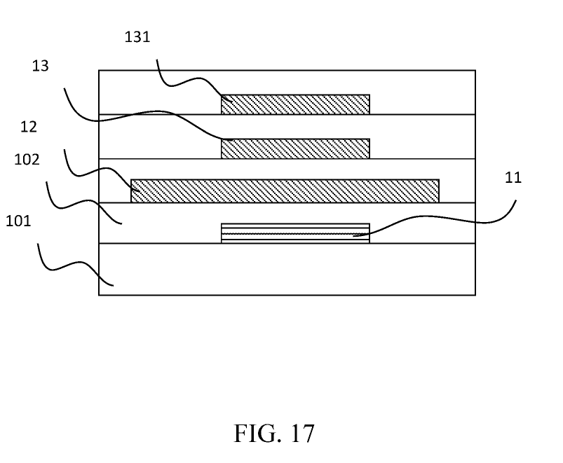

In some embodiments, as shown in FIG. 17, the second conductive layer 12, the third conductive layer 13 and the fourth conductive layer 131 may be formed of a same material such as a transparent conductive material.

In some embodiments, when forming the first conductive layer 11, a scan line Gate is formed on the substrate. For instance, as shown in FIGS. 9-12, in a signal mask process, scan lines Gate and common lines Vcom may be formed simultaneously. At least parts of the common lines may be used as the first conductive layer 11.

In some embodiments, when forming the second conductive layer 12, pixel electrodes 110, 120, 130 and 140 maybe formed simultaneously on the substrate. For instance, as shown in FIGS. 9 to 12, at least parts of the pixel electrodes 110, 120, 130 and 140 may be used as the second conductive layer 12. The material of the pixel electrodes 110, 120, 130 and 140 may be such as ITO, IZO, AZO, ATO, GZO, TCO, ZnO or poly(3,4-ethylenedioxythiophene) (PEDOT).

In some embodiments, when forming the third conductive layer 12, the material of the third conductive 13 is the same as the materials of the first metal layer or the second metal layer of the active switch TFT. For instance, as shown in FIGS. 9-12, the material of the third conductive layer 13 may be the same as the material of the second metal layer (source electrode, drain electrode) of the active switch TFT.

In some embodiments, at least one of the first conductive layer 11, the second conductive layer 12 and the third conductive layer 13 is formed of a same material as the first metal layer of the active switch TFT. For instance, Al, Ag, Cu, Mo, Cr, W, Ta, Ti, metal nitride or an alloy of a combination thereof. Also, it may be a multilayer structure having heat-resistant metal film and low-resistivity film such as a double-layer structure of a molybdenum nitride film and an aluminum film.

In some embodiments, at least one of the first conductive layer 11, the second conductive layer 12 and the third conductive layer 13 is formed of a same material as the second metal layer of the active switch. For instance, Mo, Cr, Ta, Ti or an alloy of a combination thereof.

In some embodiments, at least one of the first conductive layer 11, the second conductive layer 12 and the third conductive layer 13 is formed of a transparent conductive material such as ITO, IZO, AZO, ATO, GZO, TCO, ZnO or poly(3,4-ethylenedioxythiophene) (PEDOT).

In the embodiments of the present disclosure, as shown in FIGS. 13 and 14, the pixel circuit structure of the present disclosure comprises: a data line Data, a scan line Gate defining a pixel area with the data line Data, an active switch TFT coupled to the data line Data and the scan line Gate, a liquid crystal capacitor Clc coupled to the active switch TFT, a first storage capacitor Cst coupled to the active switch TFT, and a second storage capacitor Cnew coupled to the first storage capacitor Cst and coupled to a DC voltage Vdc.

In some embodiments, an end of the first storage capacitor Cst is coupled to the active switch TFT. Another end of the first storage capacitor Cst is coupled to a common line Vcom, as shown in FIG. 13.

In some embodiments, an end of the first storage capacitor Cst is coupled to the active switch TFT. Another end of the first storage capacitor Cast is coupled to one of the scan lines Gate (previous scan line Gate n−1), as shown in FIG. 14.

In some embodiments, the first storage capacitor Cst and the second storage capacitor Cnew are formed by the first conductive layer, the second conductive layer and the third conductive layer. The first conductive layer is coupled to the drain electrode of the active switch. The second conductive layer is coupled to a first voltage line. The third conductive layer is coupled to a second voltage line. The first conductive layer, the second conductive layer and the third conductive layer are disposed to be overlapped and at a distance separated from each other. The first conductive layer, the second conductive layer and the third conductive layer are overlapped with each other in a vertical space.

In some embodiments, the first voltage line comprises a common line Vcom.

In some embodiments, the second voltage line and the common line Vcom are overlapped in an area covered by the first conductive layer.

In some embodiments, the first voltage line comprises a previous scan line Gate n−1.

In an embodiment of the present disclosure, wherein the first conductive layer 11, the second conductive layer 12 and the third conductive layer 13 are formed of conductive metals individually. This is a particular structure of the disposition of the first conductive layer, the second conductive layer and the third conductive layer of the present disclosure. Three conductive layers (the first conductive layer 11, the second conductive layer 12 and the third conductive layer 13) are formed of the conductive metals. The conductive metals have good conductive effect. Wherein, the conductive metals of the embodiment of the present disclosure may be: Al, Mo, Cu, Ti, Ag or alloys of a combination thereof.

It has to be explained that three conductive layers (the first conductive layer 11, the second conductive layer 12 and the third conductive layer 13) formed of the conductive metals is a particular way of the embodiment of the present disclosure. The embodiment of the present disclosure may utilize other ways.

Example 1: the first conductive layer 11 and the second conductive layer 12 are formed of the conductive metals individually, and the third conductive layer 13 is formed of a conductive material. As another particular structure disposing the first conductive layer 11, the second conductive layer 12 and the third conductive layer 13 of the present disclosure, the first conductive layer 11 and the second conductive layer 12 are both formed of the conductive metal of which the conductive metal has good conductive effect; the third conductive layer 13 formed of the transparent conductive material may also achieve a conductive effect. Further, the transparent conductive material may be such as ITO, IZO, AZO, ATO, GZO, TCO, ZnO or poly(3,4-ethylenedioxythiophene) (PEDOT).

Example 2: the first conductive layer 11 is formed of a conductive metal, and the second conductive layer 12 and the third conductive layer 13 are formed of a transparent conductive material individually. As yet another particular structure disposing the first conductive layer 11, the second conductive layer 12 and the third conductive layer 13 of the present disclosure, the first conductive layer 11 is formed of a conductive metal of which the conductive metal has good conductive effect; the second conductive layer 12 and the third conductive layer 13 formed of the transparent conductive material may also achieve a conductive effect.

In an embodiment of the present disclosure, as shown in FIGS. 9-12, the second voltage line Vdc and the common line Vcom are partially overlapped spatially. In particular, the second voltage line is disposed to be overlapped with the common line in a region covered by the first conductive layer. If two or more lines are disposed in parallel, parasitic capacitors may be generated therebetween. Further, they interfere with each other. However, the generating of the parasitic capacitors may be prevented by disposing the common line Vcom and the second voltage line Vdc to be overlapped in a region covered by the first conductive layer in the present disclosure, so the ability of interference prevention may be improved.

Furthermore, the three conductive layers (the first conductive layer 11, the second conductive layer 12 and the third conductive layer 13) of an embodiment of the present disclosure are parallel to each other. Hence, they occupy smaller area of a plane space so that the effect of applying the pixel structure of the embodiment of the present disclosure to a display panel is better.

In another embodiment of the present disclosure, the embodiment of the present disclosure further discloses an array substrate. A common line, a data line and a scan line are disposed on the array substrate. The array substrate further comprises a pixel structure. The pixel structure is coupled to the data line and the scan line individually. Wherein, the common line, the data line, the scan line and the pixel structure of the array substrate of the present embodiment may be referred to the common line, the data line, the scan line and the pixel structure mentioned in the above embodiments, or the common line, the data line, the scan line and the pixel structure of the array substrate of the array substrate of the present embodiment may be referred to the common line, the data line, the scan line and the pixel structure, the cooperation and the relationship therebetween as shown in FIGS. 9-16. The array substrate of the present embodiments has a plurality of pixel structures and each of which may referred to FIGS. 9-16. The description of the pixel structure, the common line, the data line and the scan line are omitted here.

In yet another embodiment of the present disclosure, the embodiment of the present disclosure further discloses a display panel. The display panel comprises a color film substrate and an array substrate. A common line, a data line and a scan line are disposed on the array substrate. The array substrate further comprises a pixel structure. The pixel structure is coupled to the data line and the scan line, the pixel structure individually. Wherein, the common line, the data line, the scan line and the pixel structure of the array substrate of the present embodiment may be referred to the common line, the data line, the scan line and the pixel structure mentioned in the above embodiments, or the common line, the data line, the scan line and the pixel structure of the array substrate of the array substrate of the present embodiment may be referred to the common line, the data line, the scan line and the pixel structure, the cooperation and the relationship therebetween as shown in FIGS. 9-16. The array substrate of the present embodiments has a plurality of pixel structures and each of which may referred to FIGS. 9-16. The description of the pixel structure, the common line, the data line and the scan line are omitted here.

In yet another embodiment of the present disclosure, the embodiment of the present disclosure further discloses a display device. The display device comprises a display panel and a backlight module. Wherein, the display panel comprises a color film substrate and an array substrate. A common line, a data line and a scan line are disposed on the array substrate. The array substrate further comprises a pixel structure. The pixel structure is coupled to the data line and the scan line, the pixel structure individually. Wherein, the common line, the data line, the scan line and the pixel structure of the array substrate of the present embodiment may be referred to the common line, the data line, the scan line and the pixel structure mentioned in the above embodiments, or the common line, the data line, the scan line and the pixel structure of the array substrate of the array substrate of the present embodiment may be referred to the common line, the data line, the scan line and the pixel structure, the cooperation and the relationship therebetween as shown in FIGS. 9-16. The array substrate of the present embodiments has a plurality of pixel structures and each of which may referred to FIGS. 9-16. The description of the pixel structure, the common line, the data line and the scan line are omitted here. Wherein, the display device of the present embodiment may be a liquid crystal display (LCD) or other types of display device. When the display device is a LCD, the backlight module may be used as a light source for applying sufficient brightness and distributing even light source. The backlight module of the present embodiment may be a frontlight type, or may also be a backlight type. It has to be explained that the backlight modules of the present embodiment are not limited to these.

The aforementioned contents are detailed description of the present disclosure by a combination of particular preferred embodiments. The present disclosure is not limited to these descriptions of the embodiments. A person skilled in the related art is able to know that any simple modifications and alterations which do not depart from the concept of the present disclosure are intended to be comprised within the scope of the appended claims.

1. A method of manufacturing a pixel structure, comprising:
forming a first conductive layer on a substrate;
forming a second conductive layer on the substrate;
forming a third conductive layer on the substrate, wherein the first conductive layer, the second conductive layer and the third conductive layer are disposed to be overlapped and at a distance separated from each other; and the first conductive layer, the second conductive layer and the third conductive layer are overlapped with each other in a vertical space;
forming an active switch in a pixel area after forming the first conductive layer, wherein the first conductive layer is coupled to a drain electrode of the active switch; the second conductive layer is coupled to a first voltage line; the third conductive layer is coupled to a second voltage line;
forming a scan line on the substrate when forming the first conductive layer;
forming a pixel electrode on the substrate when forming the second conductive layer;
wherein a material of the third conductive layer is the same as a material of a first metal layer or a second metal layer of the active switch when forming the third conductive layer;
forming a fourth conductive layer on the third conductive layer after forming the third conductive layer, wherein the first conductive layer, the second conductive layer, the third conductive layer and the fourth conductive layer are disposed to be overlapped and at a distance separated from each other; the second conductive layer, the third conductive layer and the fourth conductive layer are formed of the same material;
wherein at least one of the first conductive layer, the second conductive layer and the third conductive layer is formed of a transparent conductive material;
wherein the second conductive layer, the third conductive layer and the fourth conductive layer are formed of the same material.

2. A method of manufacturing a pixel structure, comprising:
forming a first conductive layer on a substrate;
forming a second conductive layer on the substrate;
forming a third conductive layer on the substrate, wherein the first conductive layer, the second conductive layer and the third conductive layer are disposed to be overlapped and at a distance separated from each other; and the first conductive layer, the second conductive layer and the third conductive layer are overlapped with each other in a vertical space; and
forming an active switch in a pixel area after forming the first conductive layer, wherein the first conductive layer is coupled to a drain electrode of the active switch; the second conductive layer is coupled to a first voltage line; and the third conductive layer is coupled to a second voltage line.

3. The method of manufacturing the pixel structure as in claim 2, wherein a scan line is formed on the substrate when forming the first conductive layer.

4. The method of manufacturing the pixel structure as in claim 2, wherein a pixel electrode is formed on the substrate when forming the second conductive layer.

5. The method of manufacturing the pixel structure as in claim 3, wherein a pixel electrode is formed on the substrate when forming the second conductive layer.

6. The method of manufacturing the pixel structure as in claim 5, wherein when forming the third conductive layer, a material of the third conductive layer is the same as a material of a first metal layer or a second metal layer of the active switch.

7. The method of manufacturing the pixel structure as in claim 6, wherein at least one of the first conductive layer, the second conductive layer and the third conductive layer is formed of a material same as the material of the first metal layer of the active switch.

8. The method of manufacturing the pixel structure as in claim 7, wherein at least one of the first conductive layer, the second conductive layer and the third conductive layer is formed of a material same as the material of the second metal layer of the active switch.

9. The method of manufacturing the pixel structure as in claim 8, wherein at least one of the first conductive layer, the second conductive layer and the third conductive layer is formed of a transparent conductive material.

10. The method of manufacturing the pixel structure as in claim 9, wherein a fourth conductive layer is formed on the third conductive layer after forming the third conductive layer; the first conductive layer, the second conductive layer, the third conductive layer and the fourth conductive layer are disposed to be overlapped and at a distance separated from each other.

11. The method of manufacturing the pixel structure as in claim 10, wherein the second conductive layer, the third conductive layer and the fourth conductive layer are formed of the same material.

12. (canceled)

13. The method of manufacturing the pixel structure as in claim 2, wherein when the third conductive layer is formed, a material of the third conductive layer is the same as a material of a first metal layer or a second metal layer of the active switch.

14. The method of manufacturing the pixel structure as in claim 2, wherein at least one of the first conductive layer, the second conductive layer and the third conductive layer is formed of a material same as a material of a first metal layer of the active switch.

15. The method of manufacturing the pixel structure as in claim 2, wherein at least one of the first conductive layer, the second conductive layer and the third conductive layer is formed of a material same as a material of a second metal layer of the active switch.

16. The method of manufacturing the pixel structure as in claim 2, wherein at least one of the first conductive layer, the second conductive layer and the third conductive layer is formed of a transparent conductive material.

17. The method of manufacturing the pixel structure as in claim 2, wherein a fourth conductive layer is formed on the third conductive layer after forming the third conductive layer; the first conductive layer, the second conductive layer, the third conductive layer and the fourth conductive layer are disposed to be overlapped and at a distance separated from each other.

18. The method of manufacturing the pixel structure as in claim 17, wherein the second conductive layer, the third conductive layer and the fourth conductive layer are formed of the same material.
